(19) United States
(12) Patent Application Publication
(10) Pub. No.: US 2016/0181313 A1
(43) Pub. Date: Jun. 23, 2016

(54) METHOD OF PRODUCING SEMICONDUCTOR EPITAXIAL WAFER, SEMICONDUCTOR EPITAXIAL WAFER, AND METHOD OF PRODUCING SOLID-STATE IMAGE SENSING DEVICE

(71) Applicant: Sumco Corporation, Minato-ku Tokyo (JP)

(72) Inventors: Takeshi Kadono, Minato-ku (JP); Kazunari Kurita, Minato-ku (JP)

(73) Assignee: SUMCO CORPORATION, Minato-ku, Tokyo (JP)

(21) Appl. No.: 14/442,373

(22) PCT Filed: Nov. 11, 2013
(86) PCT No.: PCT/JP2013/006629

§ 371 Date: May 12, 2015

(30) Foreign Application Priority Data
Nov. 12, 2012 (JP) 2012 249335

(51) Int. Cl. H01L 27/146; H01L 21/322; H01L 29/36; H01L 21/02; H01L 21/265; H01L 29/167

(52) U.S. Cl. CPC H01L 27/14687; H01L 21/26566; H01L 21/26513; H01L 29/167; H01L 29/36; H01L 21/02658; H01L 21/3221; H01L 21/02381

(57) ABSTRACT

Provided is a semiconductor epitaxial wafer having metal contamination reduced by achieving higher gettering capability, a method of producing the semiconductor epitaxial wafer, and a method of producing a solid-state image sensing device using the semiconductor epitaxial wafer. The method of producing a semiconductor epitaxial wafer 100 includes a first step of irradiating a semiconductor wafer 10 containing at least one of carbon and nitrogen with cluster ions 16 thereby forming a modifying layer 18 formed from a constituent element of the cluster ions 16 contained as a solid solution, in a surface portion of the semiconductor wafer 10; and a second step of forming a first epitaxial layer 20 on the modifying layer 18 of the semiconductor wafer 10.

### TECHNICAL FIELD

The present invention relates to a method of producing a semiconductor epitaxial wafer, a semiconductor epitaxial wafer, and a method of producing a solid-state image sensing device. The present invention relates, in particular, to a method of producing a semiconductor epitaxial wafer, which can suppress metal contamination by achieving higher gettering capability.

### BACKGROUND

Metal contamination is one of the factors that deteriorate the characteristics of a semiconductor device. For example, for a back-illuminated solid-state image sensing device, metal mixed into a semiconductor epitaxial wafer to be a substrate of the device causes increased dark current in the solid-state image sensing device, and results in the formation of defects referred to as white spot defects. In recent years, back-illuminated solid-state image sensing devices have been widely used in digital video cameras and mobile phones such as smartphones, since they can directly receive light from the outside, and take sharper images or motion pictures even in dark places and the like due to the fact that a wiring layer and the like thereof are disposed at a lower layer than a sensor section. Therefore, it is desirable to reduce white spot defects as much as possible.

Mixing of metal into a wafer mainly occurs in a process of producing a semiconductor epitaxial wafer and a process of producing a solid-state image sensing device (device fabrication process). Metal contamination in the former process of producing a semiconductor epitaxial wafer may be due to heavy metal particles from components of an epitaxial growth furnace, or heavy metal particles caused by the metal corrosion of piping materials of the furnace due to chlorine-based gas used during epitaxial growth in the furnace. In recent years, such metal contaminations have been reduced to some extent by replacing components of epitaxial growth furnaces with highly corrosion resistant materials, but not to a sufficient extent. On the other hand, in the latter process of producing a solid-state image sensing device, heavy metal contamination of semiconductor substrates would occur in process steps such as ion implantation, diffusion, and oxidizing heat treatment in the producing process.

For those reasons, conventionally, heavy metal contamination of semiconductor epitaxial wafers has been prevented by forming, in the semiconductor wafer, a gettering sink for trapping the metal, or by using a substrate having high ability to trap the metal (gettering capability), such as a high boron concentration substrate.

In general, a gettering sink is formed in a semiconductor wafer by an intrinsic gettering (IG) method in which an oxygen precipitate (also referred to as a bulk micro defect: BMD) or dislocation that are crystal defects is formed within the semiconductor wafer, or an extrinsic gettering (EG) method in which the gettering sink is formed on the rear surface of the semiconductor wafer.

Here, a technique of forming a gettering site in a semiconductor wafer by ion implantation can be given as a technique for gettering heavy metal. For example, JP H06-338507 A (PTL 1) discloses a producing method, by which carbon ions are implanted through a surface of a silicon wafer to form a carbon ion implanted region, and a silicon epitaxial layer is then formed on the surface, thereby obtaining a silicon epitaxial wafer. In that technique, the carbon ion implanted region serves as a gettering site.

JP 2002-134511 A (PTL 2) describes a technique for producing a semiconductor substrate, by which a silicon substrate containing nitrogen is implanted with carbon ions to form a carbon/nitrogen mixed region, and a silicon epitaxial layer is then formed on the surface of the silicon substrate, thereby reducing white spot defects as compared to the technique described in JP H06-338507 A (PTL 1).

Further, J P 2003-163216 A (PTL 3) describes a technique of producing an epitaxial silicon wafer, by which a silicon substrate containing at least one of carbon and nitrogen is implanted with boron ions or carbon ions, and a silicon epitaxial layer is then formed on the surface of the silicon substrate, thereby obtaining an epitaxial silicon wafer which has gettering capability with no crystal defects in the epitaxial layer.

Furthermore, J P 2010-016169 A (PTL 4) describes a technique of producing an epitaxial wafer, by which a silicon substrate containing carbon is implanted with carbon ions at a position at a depth of more than 1.2 μm from the surface of the silicon substrate to form a carbon ion injected layer having a large width, and a silicon epitaxial layer is then formed on the surface of the silicon substrate, thereby obtaining an epitaxial wafer having high gettering capability with no epitaxial defects.

### CITATION LIST

### Patent Literature

PTL 1: JP H06-338507 A

PTL 2: JP 2002-134511 A

PTL 3: JP 2003-163216 A

PTL 4: JP 2010-016169 A

### SUMMARY

In all of the techniques described in PTLs 1 to 4 above, monomer ions (single ions) are implanted into a semiconductor wafer before the formation of an epitaxial layer. However, according to studies made by the inventors of the present invention, it was found that the gettering capability is insufficient even in solid-state image sensing devices produced using semiconductor epitaxial wafers subjected to monomer-ion implantation, and the semiconductor epitaxial wafers are required to achieve stronger gettering capability.

In view of the above problems, an object of the present invention is to provide a semiconductor epitaxial wafer having metal contamination reduced by achieving higher gettering capability, a method of producing the semiconductor epitaxial wafer, and a method of producing a solid-state image sensing device using the semiconductor epitaxial wafer.

According to further studies made by the inventors of the present invention, it was found that irradiating a semiconductor wafer having a bulk semiconductor wafer containing at least one of carbon and nitrogen with cluster ions is advantageous in the following points as compared with the case of implanting monomer ions. Specifically, even if irradiation with cluster ions is performed at the same acceleration voltage as the case of monomer ion implantation, the cluster ions collide with the semiconductor wafer with a lower energy per one atom or one molecule than in the case of monomer ion implantation. Further, since the irradiation can be performed with a plurality of atoms at once, a higher peak concentration is achieved in the depth direction profile of the irradiation element, which allows the peak position to further approach the surface of the semiconductor wafer. Thus, they found that the gettering capability was improved, and completed the present invention.

Specifically, a method of producing a semiconductor epitaxial wafer according to the present invention comprises: a first step of irradiating a semiconductor wafer containing at least one of carbon and nitrogen with cluster ions thereby forming a modifying layer formed from a constituent element of the cluster ions contained as a solid solution, in a surface portion of the semiconductor wafer; and a second step of forming a first epitaxial layer on the modifying layer of the semiconductor wafer.

In the present invention, the semiconductor wafer may be a silicon wafer.

Further, the semiconductor wafer may be an epitaxial wafer in which a second epitaxial layer is formed on a surface of a silicon wafer. In this case, the modifying layer is formed in a surface portion of the second epitaxial layer in the first step.

Here, the carbon concentration of the semiconductor wafer is preferably 1×10¹⁵ atoms/cm³ or more and 1×10¹⁷ atoms/cm³ or less (ASTM F123 1981), whereas the nitrogen concentration is preferably 5×10¹² atoms/cm³ or more and 5×10¹⁴ atoms/cm³ or less.

Further, the oxygen concentration of the semiconductor wafer is preferably 9×10¹⁷ atoms/cm³ or more and 18×10¹⁷ atoms/cm³ or less (ASTM F121 1979).

Preferably, after the first step and before the second step, the semiconductor wafer is subjected to heat treatment for promoting the formation of an oxygen precipitate.

Further, the cluster ions preferably contain carbon as a constituent element. More preferably, the cluster ions contain at least two kinds of elements including carbon as constituent elements. Further, the cluster ions can further contain one or more dopant elements. The dopant element(s) can be selected from the group consisting of boron, phosphorus, arsenic, and antimony.

Furthermore, the first step is preferably performed under the conditions of: an acceleration voltage of 50 keV/atom or less per carbon atom, a cluster size of 100 or less, and a carbon dose of 1×10¹⁶ atoms/cm² or less.

Next, a semiconductor epitaxial wafer of the present invention comprises: a semiconductor wafer having a bulk semiconductor wafer containing at least one of carbon and nitrogen; a modifying layer formed from a certain element contained as a solid solution in the semiconductor wafer, the modifying layer being formed in a surface portion of the semiconductor wafer; and a first epitaxial layer on the modifying layer. The half width of the concentration profile of the certain elements in the depth direction of the modifying layer is 100 nm or less.

Here, the semiconductor wafer may be a silicon wafer.

Further, the semiconductor wafer may be an epitaxial wafer in which a second epitaxial layer is formed on a surface of a silicon wafer. In this case, the modifying layer is located in a surface portion of the second epitaxial layer.

Here, the carbon concentration of the semiconductor wafer is preferably 1×10¹⁵ atoms/cm³ or more and 1×10¹⁷ atoms/cm³ or less (ASTM F123 1981), whereas the nitrogen concentration is preferably 5×10¹² atoms/cm³ or more and 5×10¹⁴ atoms/cm³ or less.

Further, the oxygen concentration of the semiconductor wafer is preferably 9×10¹⁷ atoms/cm³ or more and 18×10¹⁷ atoms/cm³ or less (ASTM F121 1979).

Furthermore, the peak of the concentration profile of the modifying layer preferably lies at a depth within 150 nm from the surface of the semiconductor wafer, whereas the peak concentration of the concentration profile of the modifying layer is preferably 1×10¹⁵ atoms/cm³ or more.

Here, the certain elements preferably include carbon. More preferably, the certain elements include at least two kinds of elements including carbon. Further, the certain elements can further contain one or more dopant elements. The dopant element(s) can be selected from the group consisting of boron, phosphorus, arsenic, and antimony.

In a method of producing a solid-state image sensing device according to the present invention, a solid-state image sensing device is formed on the first epitaxial layer located in the surface portion of the semiconductor epitaxial wafer fabricated by any one of the above producing methods or of any one of the above semiconductor epitaxial wafers.

### Advantageous Effect of Invention

According to a method of producing a semiconductor epitaxial wafer in accordance with the present invention, a semiconductor wafer having a bulk semiconductor wafer containing at least one of carbon and nitrogen with cluster ions thereby forming a modifying layer formed from a constituent element of the cluster ions contained as a solid solution, in a surface portion of the semiconductor wafer, which makes it possible to produce a semiconductor epitaxial wafer that can reduce metal contamination by achieving higher gettering capability of the modifying layer.

### BRIEF DESCRIPTION OF DRAWINGS

FIGS. 1(A) to 1(C) are schematic cross-sectional views illustrating a method of producing a semiconductor epitaxial wafer 100 according to a first embodiment of the present invention.

FIGS. 2(A) to 2(D) are schematic cross-sectional views illustrating a method of producing a semiconductor epitaxial wafer 200 according to a second embodiment of the present invention.

FIG. 3(A) is a schematic view illustrating the irradiation mechanism for irradiation with cluster ions. FIG. 3(B) is a schematic view illustrating the implantation mechanism for implanting a monomer ion.

FIG. 4 shows the carbon concentration profile of silicon wafers in Invention Example 1 and Comparative Example 1.

FIG. 5 shows the carbon concentration profile of epitaxial silicon wafers in Invention Example 1 and Comparative Example 1 of the present invention.

### DETAILED DESCRIPTION

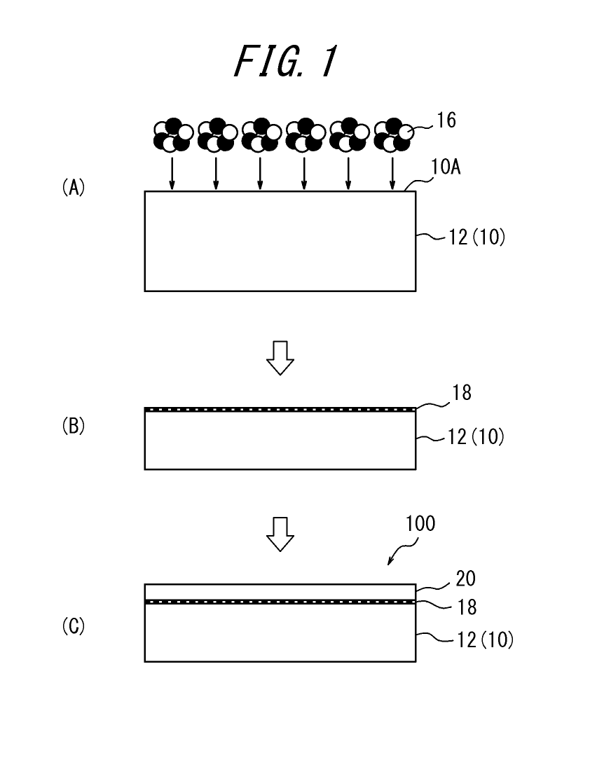

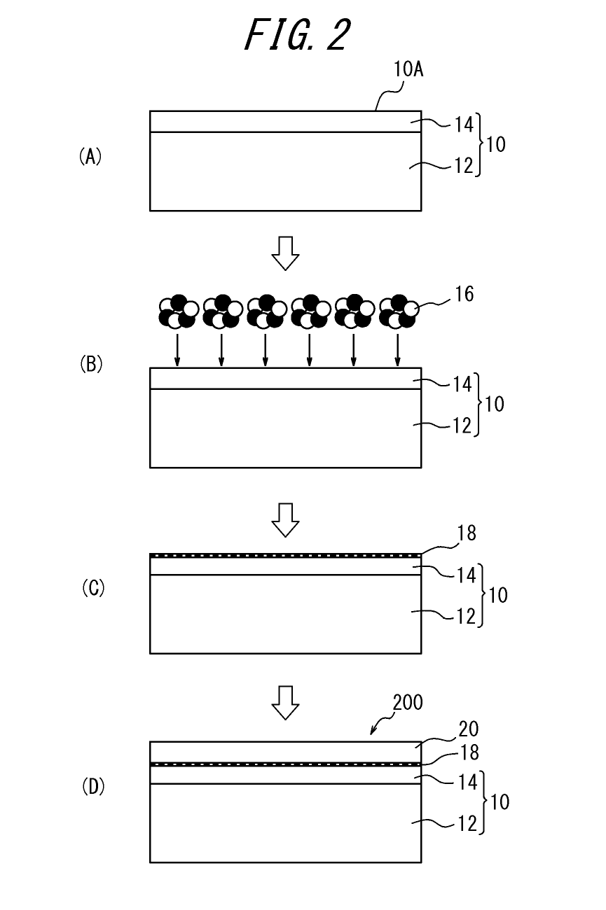

Embodiments of the present invention will now be described in detail with reference to the drawings. In principle, the same components are denoted by the same reference numeral, and the description will not be repeated. Further, in FIGS. 1(A) to 1(C) and FIGS. 2(A) to 2(D), a second epitaxial layer 14 and a first epitaxial layer 20 are exaggerated with respect to a semiconductor wafer 10 in thickness for the sake of explanation, so the thickness ratio does not conform to the actual ratio.

A method of producing a semiconductor epitaxial wafer 100 according to a first embodiment of the present invention includes, as shown in FIGS. 1(A) to 1(C), a first step (FIGS. 1(A) and 1(B)) of irradiating a semiconductor wafer 10 containing at least one of carbon and nitrogen with cluster ions 16 to form a modifying layer 18 formed from a constituent element of the cluster ions 16 contained as a solid solution in a surface portion of the semiconductor wafer 10; and a second step (FIG. 1(C)) of forming a first epitaxial layer 20 on the modifying layer 18 of the semiconductor wafer 10. FIG. 1(C) is a schematic cross-sectional view of the semiconductor epitaxial wafer 100 obtained by this producing method.

First, in this embodiment, examples of the semiconductor wafer 10 include, for example, a single crystal wafer made of silicon or a compound semiconductor (GaAs, GaN, or SiC). In general, a single crystal silicon wafer is used in cases of producing back-illuminated solid-state image sensing devices. Further, the semiconductor wafer 10 may be prepared by growing a single crystal silicon ingot by the Czochralski (CZ) method or the floating zone melting (FZ) process and slicing it with a wire saw or the like. This semiconductor wafer 10 may be made n-type or p-type by adding a given impurity dopant.

Alternatively, an epitaxial wafer in which a semiconductor epitaxial layer (second epitaxial layer) 14 is formed on a surface of the bulk semiconductor wafer 12 as shown in FIG. 2(A), can be given as an example of the semiconductor wafer 10. An example is an epitaxial silicon wafer in which a silicon epitaxial layer is formed on a surface of a bulk single crystal silicon wafer. The silicon epitaxial layer can be formed by chemical vapor deposition (CVD) process under typical conditions. The second epitaxial layer 14 preferably has a thickness in the range of 0.1 μm to 10 μm, more preferably in the range of 0.2 μm to 5 μm.

For example, in a method of producing a semiconductor epitaxial wafer 200 according to a second embodiment of the present invention, as shown in FIGS. 2(A) to 2(D), a first step (FIGS. 2(A) to 2(C)) of irradiating a surface 10A of a semiconductor wafer 10, in which a second epitaxial layer 14 is formed on a surface (at least one side) of a bulk semiconductor wafer 12, with cluster ions 16 to form a modifying layer 18 in which a constituent element of the cluster ions 16 are contained as a solid solution in the surface portion of the semiconductor wafer 10 (the surface portion of the second epitaxial layer 14 in this embodiment) is first performed. A second step (FIG. 2(D)) of forming a first epitaxial layer 20 on the modifying layer 18 of the semiconductor wafer 10 is then performed. FIG. 2(D) is a schematic cross-sectional view of the semiconductor epitaxial wafer 200 obtained by this producing method.

In the first embodiment and the second embodiment of the present invention, the semiconductor wafer 10 containing at least one of carbon and nitrogen is used as the substrate for the semiconductor epitaxial wafers 100 and 200. Carbon added into the semiconductor wafer 10 acts to promote the growth of oxygen precipitation nuclei or BMDs in the bulk. On the other hand, nitrogen added into the semiconductor wafer 10 acts to form thermally stable BMDs which are hardly eliminated by high temperature heat treatments such as an epitaxial process, in the wafer bulk. The BMDs present in the wafer have capability of trapping metal impurities mixed in from the back side of the semiconductor wafer 10 (IG capability); therefore, carbon concentration or the nitrogen concentration of the semiconductor wafer 10 can be controlled to an appropriate range, which improves the gettering capability of the semiconductor wafer 10.

The carbon concentration of the semiconductor wafer 10 is preferably 1×10¹⁵ atoms/cm³ or more and 1×10¹⁷ atoms/cm³ or less (ASTM F123 1981). Here, a carbon concentration of 1×10¹⁵ atoms/cm³ or more can lead to the promotion of precipitation of oxygen contained in the semiconductor wafer 10. Further, a carbon concentration of 1×10¹⁷ atoms/cm³ or less can prevent the formation of dislocations in growing a single crystal silicon ingot which is a material of the semiconductor wafer 10. For example, when the single crystal silicon ingot is grown by the CZ method, the carbon concentration can be adjusted by changing the load level of carbon powder loaded into a quartz crucible.

The nitrogen concentration of the semiconductor wafer 10 is preferably 5×10¹² atoms/cm³ or more and 5×10¹⁴ atoms/cm³ or less. Here, a nitrogen concentration of 5×10¹² atoms/cm³ or more allows BMDs to be formed in the semiconductor wafer 10 at a density sufficient to trap metal impurities. Further, a nitrogen concentration of 5×10¹⁴ atoms/cm³ or less can suppress the formation of epitaxial defects such as stacking faults on the surface portion of the first epitaxial layer 20. More preferably, the nitrogen concentration is 1×10¹⁴ atoms/cm³ or less. For example, when the single crystal silicon ingot is grown by the CZ method, the nitrogen concentration can be adjusted by changing the load level of silicon nitride loaded into the quartz crucible.

In order to achieve the sufficient oxygen precipitation effect of carbon and nitrogen in those concentration ranges, the oxygen concentration of the semiconductor wafer 10 is preferably 9×10¹⁷ atoms/cm³ or more. Further, the oxygen concentration is preferably 18×10¹⁷ atoms/cm³ or less (ASTM F121 1979), which can suppress epitaxial defects on the surface portion of the first epitaxial layer 20. For example, when the single crystal silicon ingot is grown by the CZ method, the oxygen concentration can be adjusted, for example by changing the rotational speed of the quartz crucible.

Here, the technical meaning of employing the step of irradiation with cluster ions, which is a characteristic step of the present invention, will be described with the operation and effect. The modifying layer 18 formed as a result of irradiation with the cluster ions 16 is a region where the constituent elements of the cluster ions 16 are localized as a solid solution at crystal interstitial positions or substitution positions in the crystal lattice of the surface portion of the semiconductor wafer 10, which region functions as a gettering site. The reason may be as follows. After the irradiation with elements such as carbon and boron in the form of cluster ions, these elements are localized at high density at substitution positions and interstitial positions in the single crystal silicon. It has been experimentally found that when carbon or boron is turned into a solid solution to the equilibrium concentration of the single crystal silicon or higher, the solid solubility of heavy metals (saturation solubility of transition metal) extremely increases. In other words, it appears that carbon or boron made into a solid solution to the equilibrium concentration or higher increases the solubility of heavy metals, which results in significantly increased rate of trapping the heavy metals.

Here, since irradiation with the cluster ions 16 is performed in the present invention, higher gettering capability can be achieved as compared with the case of implanting monomer ions; moreover, recovery heat treatment can be omitted. Therefore, the semiconductor epitaxial wafers 100 and 200 achieving higher gettering capability can be more efficiently produced, and the formation of white spot defects is expected to be suppressed in back-illuminated solid-state image sensing devices produced from the semiconductor epitaxial wafers 100 and 200 obtained by the producing methods as compared to the conventional devices.

Note that “cluster ions” herein mean clusters formed by aggregation of a plurality of atoms or molecules, which are ionized by being positively or negatively charged. A cluster is a bulk aggregate having a plurality (typically 2 to 2000) of atoms or molecules bound together.

The inventors of the present invention consider that the mechanism of achieving high gettering capability by the irradiation with the cluster ions 16 is as follows.

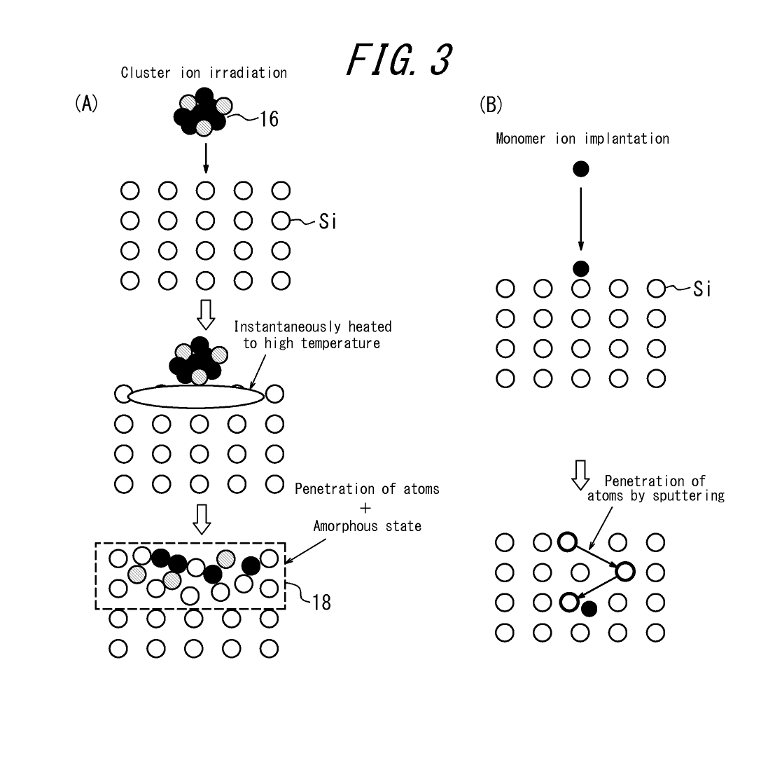

For example, when carbon monomer ions are implanted into a silicon wafer, the monomer ions sputter silicon atoms forming the silicon wafer to be implanted to a predetermined depth position in the silicon wafer, as shown in FIG. 3(B). Here, the implantation depth depends on the kind of the constituent elements of the implantation ions and the acceleration voltage of the ions. In this case, the concentration profile of carbon in the depth direction of the silicon wafer is relatively broad, and the carbon implanted region extends approximately 0.5 μm to 1 μm. When the implantation is performed simultaneously with a plurality of species of ions at the same energy, lighter elements are implanted more deeply, in other words, elements are implanted at different positions depending on their mass. Accordingly, the concentration profile of the implanted elements is broader in such a case.

Monomer ions are typically implanted at an acceleration voltage of about 150 keV to 2000 keV. However, since the ions collide with silicon atoms with the energy, which results in the degradation of crystallinity of the surface portion of the silicon wafer, to which the monomer ions are implanted. Accordingly, the crystallinity of an epitaxial layer to be grown later on the wafer surface is degraded. Further, the higher the acceleration voltage is, the more the crystallinity is degraded. Therefore, it is required to perform heat treatment for recovering the crystallinity having been disrupted, at a high temperature for a long time after ion implantation (recovery heat treatment).

On the other hand, when the silicon wafer is irradiated with cluster ions 16, for example, composed of carbon and boron, as shown in FIG. 3(A), when the silicon wafer is irradiated with the cluster ions 16, the ions are instantaneously rendered to a high temperature state of about 1350° C. to 1400° C. due to the irradiation energy, thus melting silicon. After that, the silicon is rapidly cooled to form a solid solution of carbon and boron in the vicinity of the surface of the silicon wafer. Correspondingly, a “modifying layer” herein means a layer in which the constituent elements of the ions used for irradiation form a solid solution at crystal interstitial positions or substitution positions in the crystal lattice of the surface portion of the silicon wafer. The concentration profile of carbon and boron in the depth direction of the silicon wafer is sharper as compared with the case of using monomer ions, although depending on the acceleration voltage and the cluster size of the cluster ions 16. The thickness of the region where carbon and boron used for the irradiation are localized (that is, the modifying layer) is a region of approximately 500 nm or less (for example, about 50 nm to 400 nm). Note that the elements used for the irradiation in the form of cluster ions are thermally diffused to some extent in the course of formation of the epitaxial layer 20. Accordingly, in the concentration profile of carbon and boron after the formation of the first epitaxial layer 20, broad diffusion regions are formed on both sides of the peaks indicating the localization of these elements. However, the thickness of the modifying layer does not change significantly (see FIG. 5 described below). Consequently, carbon and boron are precipitated at a high concentration in a localized region. Since the modifying layer 18 is formed in the vicinity of the surface of the silicon wafer, further proximity gettering can be performed. This is considered to result in achievement of still higher gettering capability. Note that the irradiation can be performed simultaneously with a plurality of species of ions in the form of cluster ions.

In general, irradiation with cluster ions 16 is performed at an acceleration voltage of about 10 keV/Cluster to 100 keV/Cluster. However, since a cluster is an aggregate of a plurality of atoms or molecules, the ions can be implanted at reduced energy per one atom or one molecule, which reduces damage to the crystals in the silicon wafer. Further, cluster ion irradiation does not degrade the crystallinity of a semiconductor wafer 10 as compared with monomer-ion implantation also due to the above described implantation mechanism. Accordingly, after the first step, without performing recovery heat treatment on the semiconductor wafer 10, the semiconductor wafer 10 can be transferred into an epitaxial growth apparatus to be subjected to the second step.

The cluster ions 16 may include a variety of clusters depending on the binding mode, and can be generated, for example, by known methods described in the following documents. Methods of generating gas cluster beam are described in (1) JP 09-041138 A and (2) JP 04-354865 A. Methods of generating ion beam are described in (1) Junzo Ishikawa, “Charged particle beam engineering”, ISBN 978-4-339-00734-3 CORONA PUBLISHING, (2) The Institution of Electrical Engineers of Japan, “Electron/Ion Beam Engineering”, Ohmsha, ISBN 4-88686-217-9, and (3) “Cluster Ion Beam—Basic and Applications”, THE NIKKAN KOGYO SHIMBUN, ISBN 4-526-05765-7. In general, a Nielsen ion source or a Kaufman ion source is used for generating positively charged cluster ions, whereas a high current negative ion source using volume production is used for generating negatively charged cluster ions.

The conditions for irradiation with cluster ions 16 are described below. First, examples of the elements used for the irradiation include, but not limited to, carbon, boron, phosphorus, arsenic, and antimony. However, in terms of achieving higher gettering capability, the cluster ions 16 preferably contain carbon as a constituent element. Carbon atoms at a lattice site have a smaller covalent radius than single crystal silicon, so that a compression site is produced in the silicon crystal lattice, which results in high gettering capability for attracting impurities in the lattice.

Further, the cluster ions more preferably contain at least two kinds of elements including carbon as constituent elements. Since the kinds of metals to be efficiently gettered depend on the kinds of the precipitated elements, a solid solution of two or more kinds of elements can cover a wider variety of metal contaminations. For example, carbon can efficiently getter nickel, whereas boron can efficiently getter copper and iron.

Further, the cluster ions can further contain a dopant element as the constituent elements in addition to carbon or two or more kinds of elements including carbon. The dopant element may be one or more elements selected from the group consisting of boron, phosphorus, arsenic, and antimony.

The compounds to be ionized are not limited in particular, but examples of compounds to be suitably ionized include ethane, methane, propane, dibenzyl (C₁₄H₁₄), and carbon dioxide (CO₂) as carbon sources, and diborane and decaborane (B₁₀H₁₄) as boron sources. For example, when a mixed gas of dibenzyl and decaborane is used as a material gas, a hydrogen compound cluster in which carbon, boron, and hydrogen are aggregated can be produced. Alternatively, when cyclohexane (C₆H₁₂) is used as a material gas, cluster ions formed from carbon and hydrogen can be produced. Further, in particular, CₙHₘ (3≦n≦16, 3≦m≦10) clusters produced from pyrene (C₁₆H₁₀), dibenzyl (C₁₄H₁₄), or the like is preferably used. This is because cluster ion beams of a small size can easily be formed.

Further, the acceleration voltage and the cluster size of the cluster ions 16 are controlled, thereby controlling the peak position of the concentration profile of the constituent elements in the depth direction of the modifying layer 18. “Cluster size” herein means the number of atoms or molecules constituting one cluster.

In the first step of the present invention, in terms of achieving higher gettering capability, the irradiation with the cluster ions 16 is preferably performed such that the peak of the concentration profile of the constituent elements in the depth direction of the modifying layer 18 lies at a depth within 150 nm from the surface 10A of the semiconductor wafer 10. Note that in this specification, in the case where the constituent elements include at least two kinds of elements, “the concentration profile of the constituent elements in the depth direction” means the profiles with respect to the respective single elements but not with respect to the total thereof.

For a condition required to set the peak positions to the depth level, when CₙHₘ (3≦n≦16, 3≦m≦10) is used as the cluster ions 16, the acceleration voltage per one carbon atom is set to be higher than 0 keV/atom and 50 keV/atom or less, and preferably 40 keV/atom or less. Further, the cluster size is 2 to 100, preferably 60 or less, more preferably 50 or less.

In addition, for adjusting the acceleration voltage, two methods of (1) electrostatic field acceleration and (2) oscillating field acceleration are commonly used. Examples of the former method include a method in which a plurality of electrodes are arranged at regular intervals, and the same voltage is applied therebetween, thereby forming constant acceleration fields in the direction of the axes. Examples of the latter method include a linear acceleration (linac) method in which ions are transferred in a straight line and accelerated with high-frequency waves. The cluster size can be adjusted by controlling the pressure of gas ejected from a nozzle, the pressure of a vacuum vessel, the voltage applied to the filament in the ionization, and the like. The cluster size is determined by finding the cluster number distribution by mass spectrometry using the oscillating quadrupole field or by time-of-flight mass spectrometry, and finding the mean value of the cluster numbers.

The dose of the clusters can be adjusted by controlling the ion irradiation time. In the present invention, the carbon dose is 1×10¹³ atoms/cm² to 1×10¹⁶ atoms/cm², preferably 5×10¹⁵ atoms/cm² or less. In a case of a carbon dose of less than 1×10¹³ atoms/cm², sufficient gettering capability would not be achieved, whereas a dose exceeding 1×10¹⁶ atoms/cm² would cause great damage to the epitaxial surface.

According to the present invention, as described above, it is not required to perform recovery heat treatment using a rapid heating/cooling apparatus for RTA (Rapid Thermal Annealing), RTO (Rapid Thermal Oxidation), or the like, separate from the epitaxial apparatus. This is because the crystallinity of the semiconductor wafer 10 can be sufficiently recovered by hydrogen baking performed prior to the epitaxial growth in an epitaxial apparatus for forming the first epitaxial layer 20 described below. For the conditions for hydrogen baking, the epitaxial growth apparatus has a hydrogen atmosphere inside. The semiconductor wafer 10 is placed in the furnace at a furnace temperature of 600° C. or more and 900° C. or less and heated to a temperature range of 1100° C. or more to 1200° C. or less at a heating rate of 1° C./s or higher to 15° C./s or lower, and the temperature is maintained for 30 s or more and 1 min or less. This hydrogen baking is performed essentially for removing natural oxide films formed on the wafer surface by a cleaning process prior to the epitaxial layer growth; however, the hydrogen baking under the above conditions can sufficiently recover the crystallinity of the semiconductor wafer 10.

Naturally, the recovery heat treatment may be performed using a heating apparatus separate from the epitaxial apparatus after the first step prior to the second step. This recovery heat treatment can be performed at 900° C. or more and 1200° C. or less for 10 s or more and 1 h or less. Here, the baking temperature is 900° C. or more and 1200° C. or less because when it is less than 900° C., the crystallinity recovery effect can hardly be achieved, whereas when it is more than 1200° C., slips would be formed due to the heat treatment at a high temperature and the heat load on the apparatus would be increased. Further, the heat treatment time is 10 s or more and 1 h or less because when it is less than 10 s, the recovery effect can hardly be achieved, whereas when it is more than 1 h, the productivity would drop and the heat load on the apparatus would be increased.

Such recovery heat treatment can be performed using, for example, a rapid heating/cooling apparatus for RTA or RTO, or a batch heating apparatus (vertical heat treatment apparatus or horizontal heat treatment apparatus). Since the former performs heat treatment using lamp radiation, its apparatus structure is not suitable for long time treatment, and is suitable for heat treatment for 15 min or less. On the other hand, the latter spends much time to rise the temperature to a predetermined temperature; however, it can simultaneously process a large number of wafers at once. Further, the latter performs resistance heating, which makes long time heat treatment possible. The heat treatment apparatus used can be suitably selected considering the irradiation conditions with respect to the cluster ions 16.

A silicon epitaxial layer can be given as an example of the first epitaxial layer 20 formed on the modifying layer 18, and the silicon epitaxial layer can be formed under typical conditions. For example, a source gas such as dichlorosilane or trichlorosilane can be introduced into a chamber using hydrogen as a carrier gas, so that the source material can be epitaxially grown on the semiconductor wafer 10 by CVD at a temperature in the range of approximately 1000° C. to 1200° C., although the growth temperature depends also on the source gas to be used. The thickness of the first epitaxial layer 20 is preferably in the range of 1 μm to 15 μm. When the thickness is less than 1 μm, the resistivity of the first epitaxial layer 20 would change due to out-diffusion of dopants from the semiconductor wafer 10, whereas a thickness exceeding 15 μm would affect the spectral sensitivity characteristics of the solid-state image sensing device. The first epitaxial layer 20 is used as a device layer for producing a back-illuminated solid-state image sensing device.

Preferably, after the first step and before the second step, the semiconductor wafer 10 is subjected to heat treatment for promoting the formation of an oxygen precipitate. For example, after the semiconductor wafer 10 having been irradiated with the cluster ion 16 is transferred into a vertical heating furnace, the heat treatment is performed at, for example, 600° C. or more and 900° C. or less for 15 min or more and 4 h or less. This heat treatment results in the formation of BMDs at a sufficient density, thereby achieving gettering capability against metal impurities mixed in from the back side of the semiconductor epitaxial wafers 100 and 200. Further, the heat treatment can also cover the above recovery heat treatment.

Next, the semiconductor epitaxial wafers 100 and 200 produced according to the above production methods will be described. The semiconductor epitaxial wafer 100 according to the first embodiment and the semiconductor epitaxial wafer 200 according to the second embodiment have, the semiconductor wafer 10 containing at least one of carbon and nitrogen; the modifying layer 18 formed from a certain element contained as a solid solution in the semiconductor wafer 10, the modifying layer 18 being formed on the surface of the semiconductor wafer 10; and the first epitaxial layer 20 on the modifying layer 18, as shown in FIG. 1(C) and FIG. 2(D). Here, the half width W of the concentration profile of the certain elements in the modifying layer 18 is 100 nm or less.

Specifically, according to the method of producing a semiconductor epitaxial wafer in accordance with the present invention, the elements constituting cluster ions can be precipitated at a high concentration in a localized region as compared with monomer-ion implantation, which results in the half width W of 100 nm or less. The lower limit thereof can be set to 10 nm. Note that “concentration profile in the depth direction” herein means a concentration distribution in the depth direction, which is measured by secondary ion mass spectrometry (SIMS). Further, “the half width of the concentration profile of the certain elements in the depth direction” is a half width of the concentration profile of the certain elements measured by SIMS, with the epitaxial layer being thinned to 1 μm considering the measurement accuracy if the thickness of the epitaxial layer exceeds 1 μm.

The carbon concentration semiconductor of the wafer 10 is preferably 1×10¹⁵ atoms/cm³ or more and 1×10¹⁷ atoms/cm³ or less (ASTM F123 1981), whereas the nitrogen concentration thereof is preferably 5×10¹² atoms/cm³ or more and 5×10¹⁴ atoms/cm³ or less, as stated above. Moreover, in order to achieve the sufficient oxygen precipitation effect of carbon and nitrogen in those concentration ranges, the oxygen concentration of the semiconductor wafer 10 is preferably 9×10¹⁷ atoms/cm³ or more (ASTM F121 1979) as also stated above.

Further, the certain elements are not limited in particular as long as they are elements other than silicon. However, carbon or at least two kinds of elements including carbon are preferred as described above. In addition, the certain elements can include dopant elements, and the dopant elements may be one or more elements selected from the group consisting of boron, phosphorus, arsenic, and antimony.

In terms of achieving higher gettering capability, for the semiconductor epitaxial wafers 100 and 200, the peak of the concentration profile of the modifying layer 18 lies at a depth within 150 nm from the surface of the semiconductor wafer 10. The peak concentration of the concentration profile is preferably 1×10¹⁵ atoms/cm³ or more, more preferably in the range of 1×10¹⁷ atoms/cm³ to 1×10²² atoms/cm³, more preferably in the range of 1×10¹⁹ atoms/cm³ to 1×10²¹ atoms/cm³.

Further, the thickness of the modifying layer 18 in the depth direction can be approximately in the range of 30 nm to 400 nm.

According to the semiconductor epitaxial wafers 100 and 200 of this embodiment, higher gettering capability can be achieved than conventional, which makes it possible to further suppress metal contamination.

In a method of producing a solid-state image sensing device according to an embodiment of the present invention, a solid-state image sensing device can be formed on an semiconductor epitaxial wafer produced according to the above producing methods or on the above semiconductor epitaxial wafer, specifically, on the first epitaxial layer 20 located in the surface portion of the semiconductor epitaxial wafers 100 and 200. In solid-state image sensing devices obtained by this producing method, white spot defects can be sufficiently suppressed than conventional.

Typical embodiments of the present invention have been described above; however, the present invention is not limited on those embodiments. For example, two layers of epitaxial layers may be formed on the semiconductor wafer 10.

### EXAMPLES

### Invention Examples 1 to 5

The examples of the present invention will be described below.

First, a single crystal silicon ingot containing at least one of carbon or nitrogen at a concentration shown in Table 1 was grown by the CZ method. From the obtained single crystal silicon ingot, n-type silicon wafers (diameter: 300 mm, thickness: 775 μm, dopant: phosphorus, dopant concentration: 4×10¹⁴ atoms/cm³, oxygen concentration: 15×10¹⁷ atoms) were prepared. Next, C₅H₅ clusters were generated as cluster ions using a cluster ion generator (CLARIS produced by Nissin Ion Equipment Co., Ltd.) and the surface of each silicon wafer layer was irradiated with the clusters under the conditions of dose: 9.00×10¹³ Clusters/cm² (carbon dose: 4.5×10¹⁴ atoms/cm²), and acceleration voltage: 14.77 keV/atom per one carbon atom. Subsequently, each silicon wafer was HF cleaned and then transferred into a single wafer processing epitaxial growth apparatus (produced by Applied Materials, Inc.) and subjected to hydrogen baking at 1120° C. for 30 s in the apparatus. After that, a silicon epitaxial layer (thickness: 6 μm, kind of dopant: phosphorus, dopant concentration: 1×10¹⁵ atoms/cm³) was then epitaxially grown on the silicon wafer by CVD at 1150° C. using hydrogen as a carrier gas and trichlorosilane as a source gas, thereby obtaining a epitaxial silicon wafer of the present invention.

### Comparative Examples 1 to 5

Epitaxial silicon wafers according to Comparative Examples 1 to 5 were prepared in the same manner as Invention Examples 1 to 5 except that carbon monomer ions were formed using CO₂ as a material gas and a monomer-ion implantation step was performed under the conditions of dose: 9.00×10¹³ atoms/cm² and acceleration voltage: 300 keV/atom instead of the step of irradiation with cluster ions.

### Comparative Example 6

An epitaxial silicon wafer according to Comparative Example 6 was fabricated under the same conditions as Invention Example 1 except that the irradiation with cluster ions was not performed.

### Comparative Example 7

An epitaxial silicon wafer according to Comparative Example 7 was fabricated under the same conditions as Invention Example 3 except that the irradiation with cluster ions was not performed.

### Comparative Example 8

An epitaxial silicon wafer according to Comparative Example 8 was fabricated under the same conditions as Invention Example 1 except that the irradiation with cluster ions was not performed and neither carbon nor nitrogen was added.

The samples prepared in Invention Examples and Comparative Examples above were evaluated.

### (1) SIMS

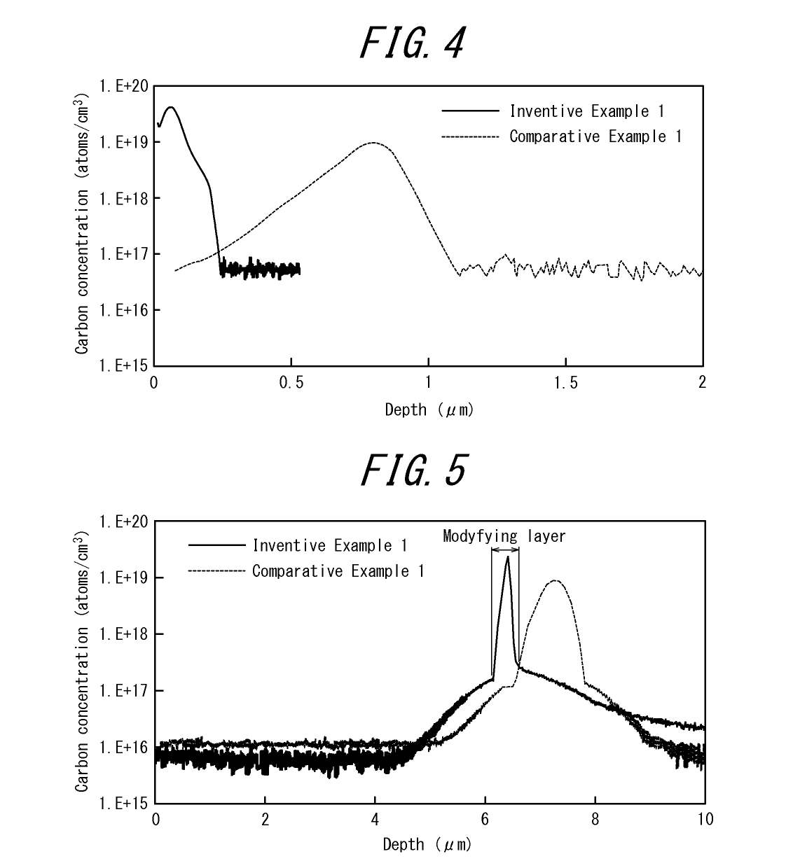

First, in order to clarify the difference between the carbon profiles immediately after the cluster ion irradiation and immediately after the monomer ion implantation, for Invention Example 1 and Comparative Example 1, SIMS was performed on the silicon wafer before the formation of an epitaxial layer. The obtained carbon concentration profiles are shown in FIG. 4 for reference. Here, the horizontal axis in FIG. 4 corresponds to the depth from the surface of the silicon wafer.

Next, the epitaxial silicon wafers of Invention Example 1 and Comparative Example 1 were subjected to the SIMS. The obtained carbon concentration profiles are shown in FIG. 5. The horizontal axis in FIG. 5 corresponds to the depth from the surface of the epitaxial silicon wafer.

Table 1 shows the half width of the carbon concentration profile of each sample fabricated in Invention Examples and Comparative Examples, obtained after performing SIMS on the epitaxial layer having been thinned to 1 μm. As mentioned above, the half width shown in Table 1 is the half width obtained by performing SIMS on the epitaxial layer having been thinned to 1 μm, so that the half width shown in Table 1 differs from the half width in FIG. 5. Table 1 also illustrates the peak positions and the peak concentrations of the concentration obtained by SIMS on the thinned epitaxial wafers.

TABLE 1

| | | | | Cluster ion irradiation conditions | | | | | | |
|---|---|---|---|---|---|---|---|---|---|---|
| | | | | (Invention Example) | | | Evaluation results | | | |
| | | | | Monomer ion implantation conditions | | | SIMS results | | | |
| | Silicon wafer | | | (Comparative Example) | | | Carbon | Carbon | | |
| | Oxygen | Carbon | Nitrogen | Ions for | Acceler- | | concen- | peak | | |
| | concen- | concen- | concen- | irradiation/ | ation | Dose | tration peak | concen- | Half | Gettering |
| | tration | tration | tration | implan- | voltage | (Clusters/cm²) | position | tration | width | capability |
| | (atoms/cm³) | (atoms/cm³) | (atoms/cm³) | tation | (keV/atom) | (atoms/cm²) | (nm) | (atoms/cm³) | (nm) | evaluation |
| Invention | 15 × 10¹⁷ | 5 × 10¹⁶ | — | C₅H₅ | 14.77 | 9.0 × 10¹³ | 42.3 | 2.21 × 10¹⁹ | 50.3 | ++ |
| Example 1 | | | | | | | | | | |
| Invention | 15 × 10¹⁷ | 10 × 10¹⁶ | — | C₅H₅ | 14.77 | 9.0 × 10¹³ | 42.3 | 2.22 × 10¹⁹ | 50.1 | ++ |
| Example 2 | | | | | | | | | | |
| Invention | 15 × 10¹⁷ | — | 1 × 10¹³ | C₅H₅ | 14.77 | 9.0 × 10¹³ | 42.3 | 2.22 × 10¹⁹ | 50.2 | ++ |
| Example 3 | | | | | | | | | | |
| Invention | 15 × 10¹⁷ | — | 10 × 10¹³ | C₅H₅ | 14.77 | 9.0 × 10¹³ | 42.3 | 2.21 × 10¹⁹ | 50.2 | ++ |
| Example 4 | | | | | | | | | | |
| Invention | 15 × 10¹⁷ | 5 × 10¹⁶ | 1 × 10¹³ | C₅H₅ | 14.77 | 9.0 × 10¹³ | 42.3 | 2.20 × 10¹⁹ | 50.2 | ++ |
| Example 5 | | | | | | | | | | |
| Comparative | 15 × 10¹⁷ | 5 × 10¹⁶ | — | C | 300 | 9.0 × 10¹³ | 750 | 8.90 × 10¹⁸ | 215 | − |
| Example 1 | | | | | | | | | | |
| Comparative | 15 × 10¹⁷ | 10 × 10¹⁶ | — | C | 300 | 9.0 × 10¹³ | 750 | 8.92 × 10¹⁸ | 214 | − |
| Example 2 | | | | | | | | | | |
| Comparative | 15 × 10¹⁷ | — | 1 × 10¹³ | C | 300 | 9.0 × 10¹³ | 751 | 8.91 × 10¹⁸ | 214 | − |
| Example 3 | | | | | | | | | | |
| Comparative | 15 × 10¹⁷ | — | 10 × 10¹³ | C | 300 | 9.0 × 10¹³ | 750 | 8.90 × 10¹⁸ | 213 | − |
| Example 4 | | | | | | | | | | |
| Comparative | 15 × 10¹⁷ | 5 × 10¹⁶ | 1 × 10¹³ | C | 300 | 9.0 × 10¹³ | 750 | 8.90 × 10¹⁸ | 216 | − |
| Example 5 | | | | | | | | | | |
| Comparative | 15 × 10¹⁷ | 5 × 10¹⁶ | — | — | — | — | — | — | — | − |
| Example 6 | | | | | | | | | | |
| Comparative | 15 × 10¹⁷ | — | 1 × 10¹³ | — | — | — | — | — | — | − |
| Example 7 | | | | | | | | | | |
| Comparative | 15 × 10¹⁷ | — | — | — | — | — | — | — | — | − |
| Example 8 | | | | | | | | | | |

As shown in FIG. 4, from the comparison between the carbon profiles of the silicon wafer immediately after the cluster ion irradiation in Invention Example 1 and the silicon wafer before forming the epitaxial layer, that is, an in-process product in Comparative Example 1 immediately after the monomer ion implantation, the carbon concentration profile is sharp in the case of the cluster ion irradiation, while the carbon concentration profile is broad in the case of the monomer ion implantation. Therefore, the carbon concentration profile after forming the epitaxial layer is presumed to have the same tendency. As can also be seen from the carbon concentration profile obtained after forming the epitaxial layer on the in-process products (FIG. 5), a modifying layer was actually formed at a higher concentration in a more localized region by the cluster ion irradiation than by the monomer ion implantation. Although not shown, the concentration profiles having the same tendency were obtained in Invention Examples 2 to 5 and Comparative Examples 2 to 5.

### (2) Gettering Capability Evaluation

The surface of the epitaxial silicon wafer in each of the samples prepared in Invention Examples and Comparative Examples was contaminated on purpose by the spin coat contamination process using a Ni contaminating agent (1.0×10¹²/cm²) and was then subjected to heat treatment at 900° C. for 30 minutes. After that, SIMS was carried out. For Invention Examples and Comparative Examples, the gettering capability was evaluated by evaluating the peak value of the Ni concentration. This evaluation was performed by classifying the values of the peak concentration of the Ni concentration profile into the criteria as follows. The obtained evaluation results are shown in Table 1.

++: 1×10¹⁷ atoms/cm³ or more

+: 7.5×10¹⁶ atoms/cm³ or more and less than 1×10¹⁷ atoms/cm³

−: less than 7.5×10¹⁶ atoms/cm³

As is clear from Table 1, with respect to each epitaxial silicon wafer of Invention Examples 1 to 5, the peak value of the Ni concentration is 1×10¹⁷ atoms/cm³ or more, and the modifying layer formed by radiation with cluster ions traps a large amount of Ni, thus achieving high gettering capability. As shown in able 1, in each of Invention Examples 1 to 5, in which the cluster ion irradiation was performed, the half width is 100 nm or less, whereas in each of Comparative Examples 1 to 5, in which the monomer ion implantation was performed, the half width is more than 100 nm. Accordingly, it can be deemed that higher gettering capability can be achieved in Invention Examples 1 to 5, in which the cluster ion irradiation was performed, since the half width of the carbon concentration profile is smaller than in Comparative Examples 1 to 5, in which the monomer ion implantation was performed. Note that in each of Comparative Examples 6 to 8, in which the cluster ion irradiation and the monomer ion implantation was not performed, the peak value of the Ni concentration was less than 7.5×10¹⁶ atoms/cm³, and the gettering capability was low.

### (3) Evaluation of BMD Density

Each of the epitaxial silicon wafers prepared in Invention Examples and Comparative Examples was subjected to heat treatments at 800° C. for 4 hours and at 1000° C. for 16 hours, and the density of BMDs in the silicon wafer (bulk wafer) was determined. The density was found by cleaving the silicon wafer, and performing light etching (etching amount: 2 μm) on the cleavage plane, followed by observing the wafer cleavage with an optical microscope.

As a result, in each of the epitaxial silicon wafers prepared in Invention Examples 1 to 5 and Comparative Examples 1 to 7, BMDs were found to be formed at 1×10⁶ atoms/cm² or more. This is considered to be attributed to the addition of carbon and/or nitrogen into the silicon wafer. On the other hand, in the sample wafer prepared by Comparative Example 8, the BMD density was 0.1×10⁶ atoms/cm² or less, since neither carbon nor nitrogen was added.

### (4) Evaluation of Epitaxial Defects

The surface of the epitaxial wafer in each of the samples prepared by Invention Examples and Comparative Examples was observed and evaluated using Surfscan SP-2 manufactured by KLA-Tencor Corporation to examine the formation of LPDs. On this occasion, the observation mode was oblique mode (oblique incidence mode), and the surface pits were examined based on the ratio of the sizes measured using wide/narrow channels. Subsequently, whether the LPDs were stacking faults (SFs) or not was evaluated by observing and evaluating the area where the LPDs are formed using a scanning electron microscope (SEM).

Consequently, for each of the epitaxial silicon wafers in Invention Examples 1 to 5 and Comparative Examples 6 to 8, the number of the SFs observed on the epitaxial layer surface was 5/wafer or less, whereas in each of the epitaxial silicon wafers in Comparative Examples 1 to 5, in which the monomer ion implantation was performed, SFs were observed to be 10/wafer or more. This can be attributed to that recovery heat treatment was not performed before the epitaxial growth process in Comparative Examples 1 to 5, which results in the epitaxial growth with the crystallinity being disrupted at the wafer surface portion due to the monomer ion implantation.

### INDUSTRIAL APPLICABILITY

The present invention makes it possible to efficiently produce a semiconductor epitaxial wafer, which can suppress metal contamination by achieving higher gettering capability. Thus, the invention is useful in the semiconductor wafer production industry.

### REFERENCE SIGNS LIST

100, 200: Semiconductor epitaxial wafer
10: Semiconductor wafer
10A: Surface of semiconductor wafer
12: Bulk semiconductor wafer
14: Second epitaxial layer
16: Cluster ions
18: Modifying layer
20: First epitaxial layer

1. A method of producing a semiconductor epitaxial wafer, comprising:
a first step of irradiating a semiconductor wafer containing at least one of carbon and nitrogen with cluster ions thereby forming a modifying layer formed from a constituent element of the cluster ions contained as a solid solution, in a surface portion of the semiconductor wafer; and
a second step of forming a first epitaxial layer on the modifying layer of the semiconductor wafer.

2. The method of producing a semiconductor epitaxial wafer, according to claim 1, wherein the semiconductor wafer is a silicon wafer.

3. The method of producing a semiconductor epitaxial wafer, according to claim 1, wherein the semiconductor wafer is an epitaxial wafer in which a second epitaxial layer is formed on a surface of a silicon wafer, and in the first step, the modifying layer is formed on a surface of the second epitaxial layer.

4. The method of producing a semiconductor epitaxial wafer, according to claim 1, wherein the carbon concentration of the semiconductor wafer is 1×10¹⁵ atoms/cm³ or more and 1×10¹⁷ atoms/cm³ or less (ASTM F123 1981), whereas the nitrogen concentration thereof is 5×10¹² atoms/cm³ or more and 5×10¹⁴ atoms/cm³ or less.

5. The method of producing a semiconductor epitaxial wafer, according to claim 1, wherein the oxygen concentration of the semiconductor wafer is 9×10¹⁷ atoms/cm³ or more and 18×10¹⁷ atoms/cm³ or less (ASTM F121 1979).

6. The method of producing a semiconductor epitaxial wafer, according to claim 1, wherein after the first step and before the second step, the semiconductor wafer is subjected to heat treatment for promoting the formation of an oxygen precipitate.

7. The method of producing a semiconductor epitaxial wafer, according to claim 1, wherein the cluster ions contain carbon as a constituent element.

8. The method of producing a semiconductor epitaxial wafer, according to claim 7, wherein the cluster ions contain at least two kinds of elements including carbon as constituent elements.

9. The method of producing a semiconductor epitaxial wafer, according to claim 7, wherein the cluster ions further contain one or more dopant elements selected from the group consisting of boron, phosphorus, arsenic, and antimony.

10. The method of producing a semiconductor epitaxial wafer, according to claim 9, wherein the first step is performed under the conditions of: an acceleration voltage of 50 keV/atom or less per one carbon atom, a cluster size of 100 or less, and a carbon dose of 1×10¹⁶ atoms/cm² or less.

11. A semiconductor epitaxial wafer, comprising:
a semiconductor wafer containing at least one of carbon and nitrogen; a modifying layer formed from a certain element contained as a solid solution in the semiconductor wafer, the modifying layer being formed in a surface portion of the semiconductor wafer; and a first epitaxial layer on the modifying layer,
wherein the half width of the concentration profile of the certain element in the depth direction of the modifying layer is 100 nm or less.

12. The semiconductor epitaxial wafer according to claim 11, wherein the semiconductor wafer is a silicon wafer.

13. The semiconductor epitaxial wafer according to claim 11, wherein the semiconductor wafer is an epitaxial wafer in which a second epitaxial layer is formed on a surface of a silicon wafer, and the modifying layer is located in a surface portion of the second epitaxial layer.

14. The semiconductor epitaxial wafer, according to claim 11, wherein the carbon concentration of the semiconductor wafer is 1×10¹⁵ atoms/cm³ or more and 1×10¹⁷ atoms/cm³ or less (ASTM F123 1981), whereas the nitrogen concentration thereof is 5×10¹² atoms/cm³ or more and 5×10¹⁴ atoms/cm³ or less.

15. The semiconductor epitaxial wafer, according to claim 11, wherein the oxygen concentration of the semiconductor wafer is 9×10¹⁷ atoms/cm³ or more and 18×10¹⁷ atoms/cm³ or less (ASTM F121 1979).

16. The semiconductor epitaxial wafer according to claim 11, wherein the peak of the concentration profile of the modifying layer lies at a depth within 150 nm from the surface of the semiconductor wafer.

17. The semiconductor epitaxial wafer according to claim 11, wherein the peak concentration of the concentration profile of the modifying layer is 1×10¹⁵ atoms/cm³ or more.

18. The semiconductor epitaxial wafer according to claim 11, wherein the certain elements include carbon.

19. The semiconductor epitaxial wafer according to claim 18, wherein the certain elements include at least two kinds of elements including carbon.

20. The semiconductor epitaxial wafer, according to claim 18, wherein the certain elements further contain one or more dopant elements selected from the group consisting of boron, phosphorus, arsenic, and antimony.

21. A method of producing a solid-state image sensing device, wherein a solid-state image sensing device is formed on the first epitaxial layer located in the surface portion of the semiconductor epitaxial wafer fabricated by the producing method according to claim 1 or of the semiconductor epitaxial wafer according to claim 11.
